(19) United States
(12) Patent Application Publication
(10) Pub. No.: US 2009/0072839 A1
(43) Pub. Date: Mar. 19, 2009

(54) Apparatus and method to detect failure of smoothing electrolytic capacitor

(75) Inventors: Myung Chul Kim, Yongin-si (KR); Jae Young Choi, Seongnam-si (KR); Jang Ho Yoon, Daejeon (KR); Song Bin Lee, Seoul (KR); Kwong Woon Lee, Suwon-si (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., Ltd., Suwon-si (KR)

(21) Appl. No.: 12/078,950

(22) Filed: Apr. 8, 2008

(30) Foreign Application Priority Data
Sep. 18, 2007 (KR) 10-2007-94484

(51) Int. Cl. G01R 31/12

(52) U.S. Cl. 324/548

(57) ABSTRACT

An apparatus and method to detect failure of an electrolytic capacitor that smoothes a DC voltage in an inverter circuit. The apparatus detects failure of a smoothing electrolytic capacitor in a motor drive inverter circuit that rectifies and smoothes an AC voltage through a rectifier and the smoothing electrolytic capacitor and converts a rectified and smoothed DC voltage into a 3-phase voltage to drive a motor. The apparatus includes a voltage meter, a current sensing unit, and a controller. The voltage meter measures a DC voltage of an inverter when the motor is not in operation. The current sensing unit measures a phase current of the motor when the motor is not in operation. The controller estimates an ESR value of the smoothing electrolytic capacitor from the DC voltage of the inverter and the motor phase current to detect failure of the smoothing electrolytic capacitor.

### CROSS-REFERENCE TO RELATED APPLICATIONS

This application claims the benefit of Korean Patent Application No. 2007-0094484, filed on Sep. 18, 2007 in the Korean Intellectual Property Office, the disclosure of which is incorporated herein by reference.

### BACKGROUND

1. Field

The present invention relates to an apparatus and method to detect failure of an electrolytic capacitor that smoothes DC voltage in an inverter circuit.

2. Description of the Related Art

Inverter circuits are power converters to convert a DC voltage into a 3-phase AC voltage (U, V, W) at any variable frequency. Due to high energy efficiency and easy output control, inverter circuits are widely used to drive motors employed in electrical products such as washing machines, refrigerators, air conditioners, microwave ovens, and elevators.

A DC voltage smoothing electrolytic capacitor is provided at a portion in the inverter circuit which rectifies and smoothes an input (AC) voltage into a DC voltage. The smoothing electrolytic capacitor functions not only to smooth a DC voltage to a specific level but also to store or discharge electrical energy. It is very important to determine the extent of deterioration of the smoothing electrolytic capacitor to detect failure of the smoothing electrolytic capacitor since the most frequent failure of the inverter circuit is caused by deterioration of the smoothing electrolytic capacitor.

When the smoothing electrolytic capacitor has failed due to deterioration, it causes overheating, resulting in breakdown of its neighboring parts or accidents such as fire. To overcome this problem, U.S. Pat. No. 5,880,589 has suggested a method to diagnose the smoothing electrolytic capacitor to detect failure of the smoothing electrolytic capacitor due to deterioration.

In the smoothing electrolytic capacitor diagnosis method described in the US patent, voltage measuring means measures the voltage of a positive terminal of the smoothing electrolytic capacitor and the voltage of the surface of the smoothing electrolytic capacitor and an A/D converter converts the measured voltages into digital values. When receiving the digital values, a CPU divides the difference between the positive terminal voltage and the surface voltage of the smoothing electrolytic capacitor by the surface voltage and determines, based on the divided value, whether or not the smoothing electrolytic capacitor has failed.

However, to detect the surface voltage of the smoothing electrolytic capacitor, this smoothing electrolytic capacitor diagnosis method requires that additional voltage measuring means (for example, wires) be attached to the surface of the smoothing electrolytic capacitor, thereby lowering the PCB productivity and increasing the manufacturing costs.

### SUMMARY

Therefore, it is an aspect of the invention to provide an apparatus and method to detect failure of a smoothing electrolytic capacitor, which can accurately detect failure of the smoothing electrolytic capacitor due to deterioration by estimating ESR and C values of the smoothing electrolytic capacitor from an inverter DC voltage and a motor phase current without any additional circuit.

It is another aspect of the invention to provide an apparatus and method to detect failure of a smoothing electrolytic capacitor, which can detect failure of the smoothing electrolytic capacitor in real time by estimating ESR and C values of the smoothing electrolytic capacitor through a switching operation to detect failure of the smoothing electrolytic capacitor in a discharge duration of the smoothing electrolytic capacitor.

Additional aspects and/or advantages of the invention will be set forth in part in the description which follows and, in part, will be apparent from the description, or may be learned by practice of the invention.

The foregoing and/or other aspects of the present invention may be achieved by providing an apparatus to detect failure of a smoothing electrolytic capacitor in a motor drive inverter circuit that rectifies and smoothes an AC voltage through a rectifier and the smoothing electrolytic capacitor and converts a rectified and smoothed DC voltage into a 3-phase voltage to drive a motor, the apparatus including a voltage meter to measure a DC voltage of an inverter when the motor is not in operation; a current sensing unit to measure a phase current of the motor when the motor is not in operation; and a controller to estimate an equivalent series resistance (ESR) value of the smoothing electrolytic capacitor from the measured DC voltage of the inverter and the measured motor phase current to detect failure of the smoothing electrolytic capacitor.

The controller detects failure of the smoothing electrolytic capacitor when the motor is not in operation or before the motor is activated.

The controller controls a switching operation of the inverter to detect failure of the smoothing electrolytic capacitor in a discharge duration of the smoothing electrolytic capacitor.

The controller estimates an ESR value of the smoothing electrolytic capacitor using the following equation from a change that has been made in the DC voltage of the inverter during switching of a second switch provided at an upper portion in the inverter while a first switch provided at a lower portion in the inverter is on:

$$ESR = {\hat{R}}_{c} = \frac{Δ {e}_{c , avg}}{{I}_{as , dc}} ,$$

where Δe_{c,avg} is a change of the inverter DC voltage and I_{as,dc} is an average of the motor phase current.

When the estimated ESR value of the smoothing electrolytic capacitor is 10 or more times higher than an initial value, the controller determines that the smoothing electrolytic capacitor has deteriorated and thus detects that a failure has occurred in the smoothing electrolytic capacitor.

The controller estimates a capacitance (C) value of the smoothing electrolytic capacitor using the following equation from a change that has been made in the DC voltage of the inverter during switching of a second switch provided at an upper portion in the inverter while a first switch provided at a lower portion in the inverter is on:

$$\hat{C} = \frac{{DT}_{s} \cdot {I}_{as , dc}}{Δ {v}_{c}} ,$$

where D is a duty, Ts is a switching frequency, Δv_{c} is a discharged level of the inverter DC voltage, and I_{as,dc} is an average of the motor phase current.

When the estimated C value of the smoothing electrolytic capacitor is 0.6 or less times an initial value, the controller determines that the smoothing electrolytic capacitor has deteriorated and thus detects that a failure has occurred in the smoothing electrolytic capacitor.

The apparatus further includes a display unit to display detection of failure of the smoothing electrolytic capacitor.

The voltage meter detects a DC voltage applied between two terminals of the smoothing electrolytic capacitor in a discharge duration of the smoothing electrolytic capacitor.

The foregoing and/or other aspects of the present invention may also be achieved by providing a method to detect failure of a smoothing electrolytic capacitor in a motor drive inverter circuit that rectifies and smoothes an AC voltage through a rectifier and the smoothing electrolytic capacitor and converts a rectified and smoothed DC voltage into a 3-phase voltage to drive a motor, the method including measuring a DC voltage of an inverter when the motor is not in operation; measuring a phase current of the motor when the motor is not in operation; and estimating an equivalent series resistance (ESR) value of the smoothing electrolytic capacitor from the measured DC voltage of the inverter and the measured motor phase current to detect failure of the smoothing electrolytic capacitor.

Detecting the failure of the smoothing electrolytic capacitor includes detecting failure of the smoothing electrolytic capacitor when the motor is not in operation or before the motor is activated.

Detecting the failure of the smoothing electrolytic capacitor includes switching a second switch provided at an upper portion in the inverter while a first switch provided at a lower portion in the inverter is on in order to estimate an ESR value of the smoothing electrolytic capacitor.

Estimating the ESR value of the smoothing electrolytic capacitor includes estimating an ESR value of the smoothing electrolytic capacitor using the following equation from a change that has been made in the DC voltage of the inverter during the switching of the second switch:

$$ESR = {\hat{R}}_{c} = \frac{Δ {e}_{c , avg}}{{I}_{as , dc}} ,$$

where Δe_{c,avg} is a change of the inverter DC voltage and I_{as,dc} is an average of the motor phase current.

Detecting the failure of the smoothing electrolytic capacitor includes determining, when the estimated ESR value of the smoothing electrolytic capacitor is 10 or more times higher than an initial value, that the smoothing electrolytic capacitor has deteriorated and thus detects that a failure has occurred in the smoothing electrolytic capacitor.

Detecting the failure of the smoothing electrolytic capacitor includes switching a second switch provided at an upper portion in the inverter while a first switch provided at a lower portion in the inverter is on in order to estimate a capacitance (C) value of the smoothing electrolytic capacitor.

Estimating the capacitance (C) value of the smoothing electrolytic capacitor includes estimating a capacitance (C) value of the smoothing electrolytic capacitor using the following equation from a change that has been made in the DC voltage of the inverter during the switching of the second switch:

$$\hat{C} = \frac{{DT}_{s} \cdot {I}_{as , dc}}{Δ {v}_{c}} ,$$

where D is a duty, Ts is a switching frequency, Δv_{c} is a discharged level of the inverter DC voltage, and I_{as,dc} is an average of the motor phase current.

Detecting the failure of the smoothing electrolytic capacitor includes determining, when the estimated C value of the smoothing electrolytic capacitor is 0.6 or less times an initial value, that the smoothing electrolytic capacitor has deteriorated and thus detects that a failure has occurred in the smoothing electrolytic capacitor.

The method further includes displaying detection of failure of the smoothing electrolytic capacitor.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a circuit diagram of an inverter circuit to drive a motor according to an embodiment of the invention;

FIG. 2 is a first simplified equivalent circuit diagram of the inverter circuit of FIG. 1 to detect failure of a smoothing electrolytic capacitor according to an embodiment of the invention;

FIG. 3 is a second simplified equivalent circuit diagram of the inverter circuit of FIG. 1 to detect failure of a smoothing electrolytic capacitor according to an embodiment of the invention;

FIG. 4 is a waveform diagram illustrating simulation results of the inverter circuit of FIG. 1;

FIG. 5 is a waveform diagram illustrating simulation results of the equivalent circuits of FIGS. 2 and 3 when the smoothing electrolytic capacitor is in a normal state;

FIG. 6 is a waveform diagram illustrating simulation results of the equivalent circuits of FIGS. 2 and 3 when the smoothing electrolytic capacitor is in a deteriorated state;

FIG. 7 is a table describing a comparison of measured ESR and C values with those estimated from experiments to detect failure of the smoothing electrolytic capacitor according to an embodiment of the invention; and

FIG. 8 is a graph showing changes of ESR and C values with respect to temperature when the smoothing electrolytic capacitor is in a normal or deteriorated state.

### DETAILED DESCRIPTION OF THE EMBODIMENTS

Reference will now be made in detail to the embodiments of the present invention, examples of which are illustrated in the accompanying drawings, wherein like reference numerals refer to the like elements throughout. The embodiments are described below to explain the present invention by referring to the figures.

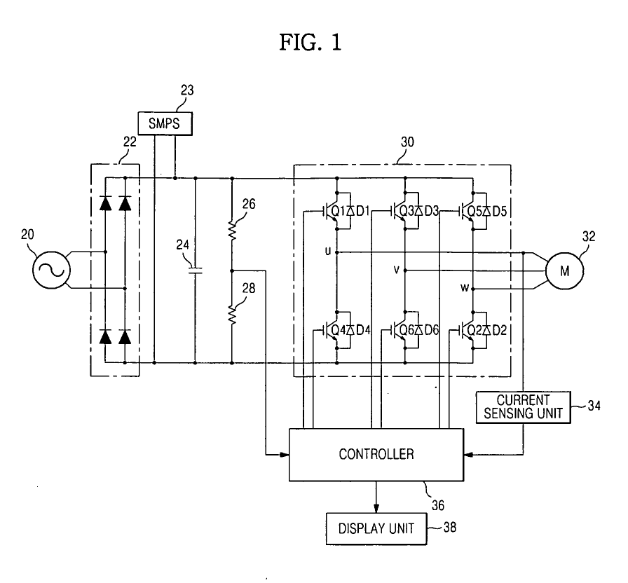

FIG. 1 is a circuit diagram of an inverter circuit to drive a motor according to an embodiment of the invention.

As shown in FIG. 1, the inverter circuit, which detects failure of an electrolytic capacitor that smoothes an inverter DC voltage according to the invention, includes a rectifier 22, a switching mode power supply (SMPS) 23, a smoothing electrolytic capacitor 24, voltage divider resistors 26 and 28, an inverter 30, a motor 32, a current sensing unit 34, a controller 36, and a display unit 38. The rectifier 22 rectifies an AC power supply voltage 20 of 220V, 60 Hz or the like. The SMPS 23 is connected to the rectifier 22 to supply a control DC voltage. The smoothing electrolytic capacitor 24 is connected to the rectifier 22 to smooth the rectified DC voltage and to store electrical energy. The divider resistors 26 and 28 are connected to the smoothing electrolytic capacitor 24 to measure a DC voltage applied between two terminals of the smoothing electrolytic capacitor 24.

The inverter 30 is an intelligent power module (IPM) including 6 switching elements (IGBT) Q1-Q6 and 6 diodes (FRD) D1-D6 connected in a full bridge configuration to convert a DC voltage into a 3-phase AC voltage and to provide the 3-phase AC voltage to the motor 32.

The current sensing unit 34 measures the level of a load (phase) current provided to the motor 32 and applies the measured current level to an A/D converter of the controller 36.

The controller 36 is a microprocessor that controls on/off of the 6 switching elements Q1 to Q6 and creates any 3-phase AC voltage at any frequency. Driving of the motor 32 through PWM control is a well-known technology.

In order to detect failure of the electrolytic capacitor 24 that smoothes the DC voltage of the inverter 30, the controller 36 estimates an equivalent series resistance (ESR) value and a pure capacitance (C) value of the smoothing electrolytic capacitor 24 by performing unipolar-switching of an upper switch (for example, Q1) and a lower switch (for example, Q6) of the inverter 30 in a discharge duration of the smoothing electrolytic capacitor 24 when the motor 32 is not in operation or before the motor 32 is activated. To accomplish this, the controller 36 switches on/off the upper switch Q1 or turns off the upper switch Q1 while the lower switch Q6 is on and estimates the ESR and C values of the smoothing electrolytic capacitor 24 from phase currents of the motor 32 and DC voltages of the inverter 30 before and after the switching of the upper switch Q1.

When the estimated ESR value of the smoothing electrolytic capacitor 24 is 10 or more times higher than the initial (normal) value (for example when the estimated ESR value is about 2Ω or higher), the controller 36 determines that the smoothing electrolytic capacitor 24 has deteriorated and thus detects that a failure has occurred in the smoothing electrolytic capacitor 24. When the estimated C value of the smoothing electrolytic capacitor 24 is 0.6 or less times the initial (normal) value (for example when it is about 400 μF or less), the controller 36 determines that the smoothing electrolytic capacitor 24 has deteriorated and thus detects that a failure has occurred in the smoothing electrolytic capacitor 24. When failure of the smoothing electrolytic capacitor 24 has been detected, the controller 36 deactivates the inverter 30 and displays the detection result of the smoothing electrolytic capacitor 24, which indicates that it has failed due to deterioration, on the display unit 38.

Reference will now be made to operations and advantages of the device and method to detect failure of the smoothing electrolytic capacitor constructed as described above.

As shown in FIG. 1, when an AC power supply voltage 20 of 200V, 60 Hz or the like is supplied, the rectifier 22 rectifies the AC voltage and the smoothing electrolytic capacitor 24 connected to the rectifier 22 smoothes the rectified DC voltage to convert it into a DC voltage and outputs the DC voltage.

The inverter 30 converts the DC voltage output from the smoothing electrolytic capacitor 24 into any 3-phase AC voltage at any variable frequency through pulse width modulation (PWM) and provides the 3-phase AC voltage to the motor 32. As the 3-phase AC voltage is provided to the motor 32, the motor 32 begins to drive. A detailed description of the driving of the motor 32 through PWM control is omitted herein since it is a well-known technology.

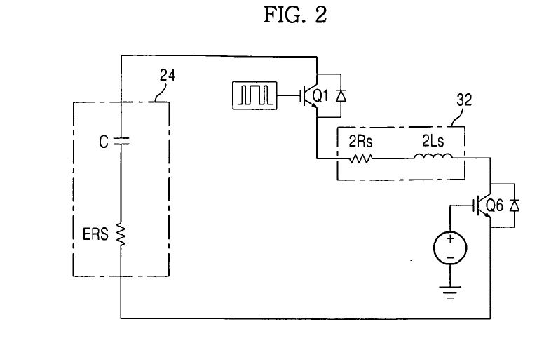

In order to detect failure of the electrolytic capacitor 24 that smoothes the DC voltage of the inverter 30, the controller 36 estimates ESR and C values of the smoothing electrolytic capacitor 24 by performing unipolar-switching of an upper switch (for example, Q1) and a lower switch (for example, Q6) of the inverter 30 in a discharge duration of the smoothing electrolytic capacitor 24 when the motor 32 is not in operation or before the motor 32 is activated. How failure (or the extent of degradation) of the smoothing electrolytic capacitor 24 is detected by estimating the ESR and C values of the smoothing electrolytic capacitor 24 will now be described in more detail with reference to FIGS. 2 to 6.

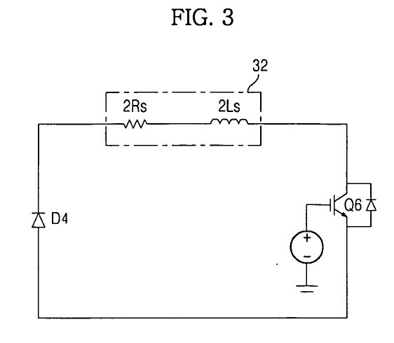

FIG. 2 is a first simplified equivalent circuit diagram of the inverter circuit of FIG. 1 to detect failure of a smoothing electrolytic capacitor according to an embodiment of the invention and FIG. 3 is a second simplified equivalent circuit diagram of the inverter circuit of FIG. 1 to detect failure of a smoothing electrolytic capacitor according to an embodiment of the invention when the upper switch Q1 and the lower switch Q6 of the inverter 30 are unipolar-switched during a discharge duration of the smoothing electrolytic capacitor 24.

Specifically, FIG. 2 shows a closed circuit when the lower switch Q1 is switched on/off while the lower switch Q6 is on and FIG. 3 shows a closed circuit when the lower switch Q1 is turned off while the lower switch Q6 is on, where U and V phases of the motor 32 are simplified as “2Rs” and “2Ls”, respectively, since a stator wiring resistance Rs and a stator wiring inductance Ls are present in the U and V phases of the motor 32.

The smoothing electrolytic capacitor 24 can be modeled as an equivalent series-connected circuit of a pure capacitance C, an equivalent series resistance (ESR), and an equivalent series inductance (ESL). The ESL is negligible since the influence of the ESL is very small in a low frequency range of 60 Hz-1 KHz. The ESR generally has a very small value (e.g., hundreds of mQ) and the value of the ESR gradually increases as the smoothing electrolytic capacitor 24 deteriorates. If the smoothing electrolytic capacitor 24 deteriorates, the electrolyte in the smoothing electrolytic capacitor 24 is vaporized, exiting the smoothing electrolytic capacitor 24. This decreases the inter-electrode region and increases the ESR, thereby decreasing the electric capacitance. The increase of the ESR increases losses and accelerates the deterioration, thereby causing a failure.

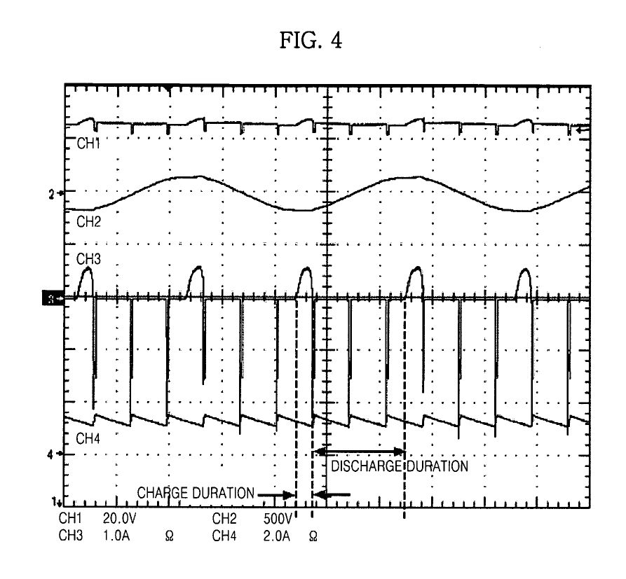

FIGS. 4 to 6 show current and voltage waveforms as simulation results of the inverter circuit of FIG. 1 to detect failure of the smoothing electrolytic capacitor 24.

Specifically, FIG. 4 is a waveform diagram illustrating simulation results of the inverter circuit of FIG. 1, where “CH1” denotes a DC voltage of the inverter 30 applied between the two terminals of the smoothing electrolytic capacitor 24, “CH2” denotes an input voltage of the AC power supply 20, “CH3” denotes a current of the smoothing electrolytic capacitor 24, and “CH4” denotes a phase current of the motor 32.

As can be seen from FIG. 4, the smoothing electrolytic capacitor 24 is discharged to provide a current to the motor 32 when the input voltage of the AC power supply 20 is less than the DC voltage of the inverter 30. The DC voltage of the inverter 30 increases in the charge duration of the smoothing electrolytic capacitor 24 and decreases in the discharge duration of the smoothing electrolytic capacitor 24.

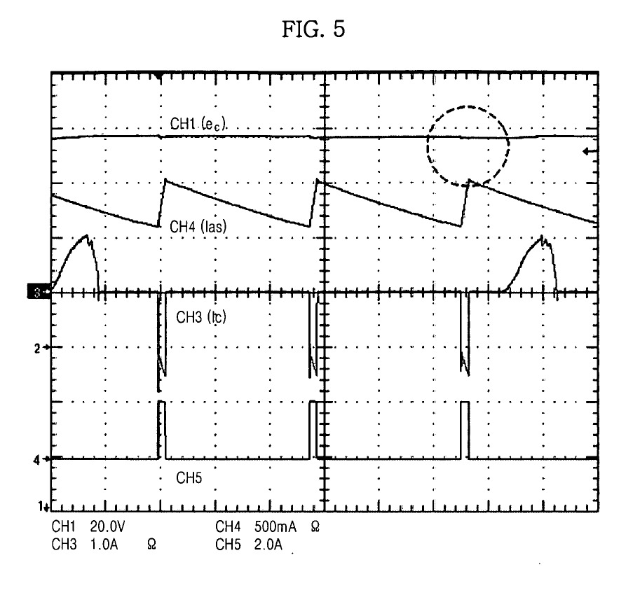

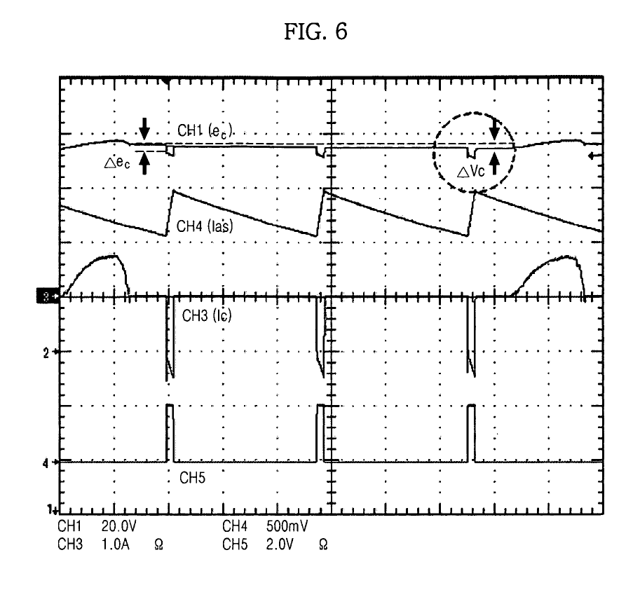

FIG. 5 is a waveform diagram illustrating simulation results of the equivalent circuits of FIGS. 2 and 3 when the smoothing electrolytic capacitor is in a normal state and FIG. 6 is a waveform diagram illustrating simulation results of the equivalent circuits of FIGS. 2 and 3 when the smoothing electrolytic capacitor is in a deteriorated state. These figures are enlarged waveform diagrams of the discharge duration of the smoothing electrolytic capacitor 24.

In FIGS. 5 and 6, “CH1” denotes a DC voltage ec of the inverter 30 applied between the two terminals of the smoothing electrolytic capacitor 24, “CH3” denotes a current Ic of the smoothing electrolytic capacitor 24, “CH4” denotes a phase current “Ias” of the motor 32, and “CH5” denotes a switching signal to switch on/off the upper switch Q1 of the inverter 30.

As can be seen from dotted circles in FIGS. 5 and 6, the voltage e_{c} is reduced as the ESR value increases due to the deterioration of the smoothing electrolytic capacitor 24 while the voltage ec is not reduced when the smoothing electrolytic capacitor 24 is in a normal state.

Accordingly, the ESR value of the smoothing electrolytic capacitor 24 can be estimated using Equation 1.

$$ESR = {\hat{R}}_{c} = \frac{Δ {e}_{c , avg}}{{I}_{as , dc}} , \qquad EQUATION 1$$

where Δ_{ec,avg} is a change of the inverter DC voltage and I_{as,dc} is an average of the motor phase current.

The discharge amount of the smoothing electrolytic capacitor 24 can be obtained during one discharge cycle of the smoothing electrolytic capacitor 24 and the C value of the smoothing electrolytic capacitor 24 can be estimated using Equation 2.

$$\hat{C} = \frac{{DT}_{s} \cdot {I}_{as , dc}}{Δ {v}_{c}} , \qquad EQUATION 2$$

where D is a duty, Tₛ is a switching frequency, Δv_{c} is a discharged level of the inverter DC voltage, and I_{as,dc} is an average of the motor phase current.

In this manner, the ESR and C values of the smoothing electrolytic capacitor 24 are estimated from the inverter DC voltage e_{c} and the motor phase current Iₐₛ.

Accordingly, when the estimated ESR value of the smoothing electrolytic capacitor 24 is 10 or more times higher than the initial (normal) value (for example when the estimated ESR value is about 2Ω or higher), the controller 36 determines that the smoothing electrolytic capacitor 24 has deteriorated and thus detects that failure has occurred in the status of the smoothing electrolytic capacitor 24. When the estimated C value of the smoothing electrolytic capacitor 24 is 0.6 or less times the initial (normal) value (for example when it is about 400 μF or less), the controller 36 determines that the smoothing electrolytic capacitor 24 has deteriorated and thus detects that failure has occurred in the status of the smoothing electrolytic capacitor 24. When failure of the smoothing electrolytic capacitor 24 has been detected, the inverter 30 is deactivated, thereby preventing breakdown of parts or fire which would otherwise occur due to the failure of the smoothing electrolytic capacitor 24.

The controller 36 also displays the detection result of the smoothing electrolytic capacitor 24, which indicates that it has failed due to deterioration, on the display unit 38, thereby allowing the user to take action against the failure of the smoothing electrolytic capacitor 24.

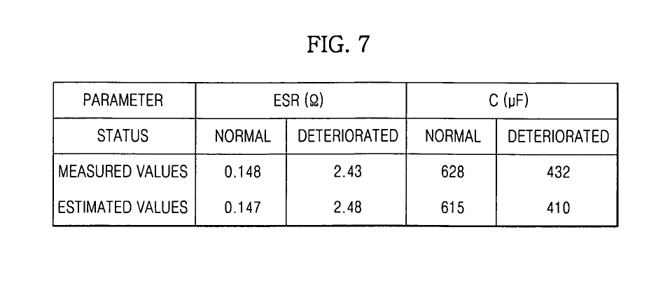

FIG. 7 is a table describing a comparison of measured ESR and C values with those estimated from experiments to detect failure of the smoothing electrolytic capacitor according to an embodiment of the invention. Specifically, the table shows a comparison of measured ESR and C values with those estimated from phase currents of the motor 32 and DC voltages of the inverter 30 through unipolar-switching of the inverter 30 in a discharge duration of the smoothing electrolytic capacitor 24.

As shown in FIG. 7, in the case of ESR values, when the smoothing electrolytic capacitor 24 is in a normal state, the estimated value is 0.147Ω while the measured value is 0.148Ω, which is almost the same as the estimated value, and, when the smoothing electrolytic capacitor 24 is in a deteriorated state, the estimated value is 2.48Ω while the measured value is 2.43Ω, which has a negligible difference of 0.05Ω from the estimated value.

In the case of C values, when the smoothing electrolytic capacitor 24 is in a normal state, the estimated value is 615 μF while the measured value is 628 μF, which has a negligible difference of 13 μF from the estimated value, and, when the smoothing electrolytic capacitor 24 is in a deteriorated state, the estimated value is 410 μF while the measured value is 432 μF, which has a negligible difference of 22 μF from the estimated value.

Thus, we can see that ESR and C values estimated from phase currents of the motor 32 and DC voltages of the inverter 30 measured by performing unipolar-switching of the inverter 30 in a discharge duration of the smoothing electrolytic capacitor 24 24 in order to detect failure of the smoothing electrolytic capacitor 24 are almost the same as measured ESR and C values.

In addition, the internal temperature of the smoothing electrolytic capacitor 24 can be estimated from the relationship of ESR and C values with temperature since ESR and C values vary depending on temperature.

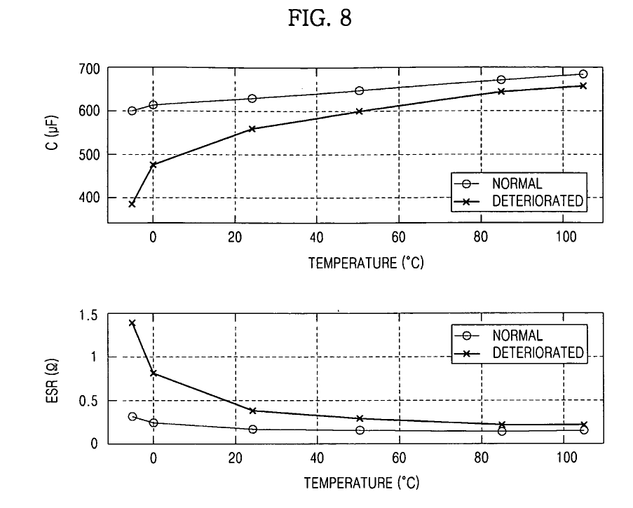

FIG. 8 is a graph showing changes of ESR and C values with respect to temperature when the smoothing electrolytic capacitor is in a normal or deteriorated state.

In FIG. 8, it can be seen that ESR and C values greatly vary depending on temperature when the smoothing electrolytic capacitor 24 is in a deteriorated state while they do not greatly vary depending on temperature when the smoothing electrolytic capacitor 24 is in a normal state.

As is apparent from the above description, an apparatus and method to detect failure of a smoothing electrolytic capacitor according to the present invention has a variety of advantages. For example, it is possible to accurately detect failure of the smoothing electrolytic capacitor due to deterioration by estimating ESR and C values of the smoothing electrolytic capacitor from an inverter DC voltage and a motor phase current without any additional circuit. It is also possible to detect failure of the smoothing electrolytic capacitor in real time by estimating ESR and C values of the smoothing electrolytic capacitor through a switching operation to detect failure of the smoothing electrolytic capacitor in a discharge duration of the smoothing electrolytic capacitor.

Although a few embodiments of the present invention have been shown and described, it would be appreciated by those skilled in the art that changes may be made in these embodiments without departing from the principles and spirit of the invention, the scope of which is defined in the claims and their equivalents.

What is claimed is:

1. An apparatus to detect failure of a smoothing electrolytic capacitor in a motor drive inverter circuit that rectifies and smoothes an AC voltage through a rectifier and the smoothing electrolytic capacitor and converts a rectified and smoothed DC voltage into a 3-phase voltage to drive a motor, the apparatus comprising:
a voltage meter to measure a DC voltage of an inverter when the motor is not in operation;
a current sensing unit to measure a phase current of the motor when the motor is not in operation; and
a controller to estimate an equivalent series resistance (ESR) value of the smoothing electrolytic capacitor from the measured DC voltage of the inverter and the measured motor phase current to detect failure of the smoothing electrolytic capacitor.

2. The apparatus according to claim 1, wherein the controller detects failure of the smoothing electrolytic capacitor when the motor is not in operation or before the motor is activated.

3. The apparatus according to claim 2, wherein the controller controls a switching operation of the inverter to detect failure of the smoothing electrolytic capacitor in a discharge duration of the smoothing electrolytic capacitor.

4. The apparatus according to claim 3, wherein the controller estimates an ESR value of the smoothing electrolytic capacitor using the following equation from a change that has been made in the DC voltage of the inverter during switching of a second switch provided at an upper portion in the inverter while a first switch provided at a lower portion in the inverter is on:
$$ESR = {\hat{R}}_{c} = \frac{Δ {e}_{c , avg}}{{I}_{as , dc}} ,$$
where Δe_{c,avg} is a change of the inverter DC voltage and I_{as,dc} is an average of the motor phase current.

5. The apparatus according to claim 4, wherein, when the estimated ESR value of the smoothing electrolytic capacitor is 10 or more times higher than an initial value, the controller determines that the smoothing electrolytic capacitor has deteriorated and thus detects that a failure has occurred in the smoothing electrolytic capacitor.

6. The apparatus according to claim 3, wherein the controller estimates a capacitance (C) value of the smoothing electrolytic capacitor using the following equation from a change that has been made in the DC voltage of the inverter during switching of a second switch provided at an upper portion in the inverter while a first switch provided at a lower portion in the inverter is on:
$$\hat{C} = \frac{{DT}_{s} \cdot {I}_{as , dc}}{Δ {v}_{c}} ,$$
where D is a duty, Tₛ is a switching frequency, Δv_{c} is a discharged level of the inverter DC voltage, and I_{as,dc} is an average of the motor phase current.

7. The apparatus according to claim 6, wherein when the estimated C value of the smoothing electrolytic capacitor is 0.6 or less times an initial value, the controller determines that the smoothing electrolytic capacitor has deteriorated and thus detects that a failure has occurred in the smoothing electrolytic capacitor.

8. The apparatus according to claim 1, further comprising a display unit to display detection of failure of the smoothing electrolytic capacitor.

9. The apparatus according to claim 2, wherein the voltage meter detects a DC voltage applied between two terminals of the smoothing electrolytic capacitor in a discharge duration of the smoothing electrolytic capacitor.

10. A method to detect failure of a smoothing electrolytic capacitor in a motor drive inverter circuit that rectifies and smoothes an AC voltage through a rectifier and the smoothing electrolytic capacitor and converts a rectified and smoothed DC voltage into a 3-phase voltage to drive a motor, the method comprising:
measuring a DC voltage of an inverter when the motor is not in operation;
measuring a phase current of the motor when the motor is not in operation; and
estimating an equivalent series resistance (ESR) value of the smoothing electrolytic capacitor from the measured DC voltage of the inverter and the measured motor phase current to detect failure of the smoothing electrolytic capacitor.

11. The method according to claim 10, wherein detecting the failure of the smoothing electrolytic capacitor includes detecting failure of the smoothing electrolytic capacitor when the motor is not in operation or before the motor is activated.

12. The method according to claim 11, wherein detecting the failure of the smoothing electrolytic capacitor includes switching a second switch provided at an upper portion in the inverter while a first switch provided at a lower portion in the inverter is on in order to estimate an ESR value of the smoothing electrolytic capacitor.

13. The method according to claim 12, wherein estimating the ESR value of the smoothing electrolytic capacitor includes estimating an ESR value of the smoothing electrolytic capacitor using the following equation from a change that has been made in the DC voltage of the inverter during the switching of the second switch:
$$ESR = {\hat{R}}_{c} = \frac{Δ {e}_{c , avg}}{{I}_{as , dc}} ,$$
where Δe_{c,avg} is a change of the inverter DC voltage and I_{as,dc} is an average of the motor phase current.

14. The method according to claim 13, wherein detecting the failure of the smoothing electrolytic capacitor includes determining, when the estimated ESR value of the smoothing electrolytic capacitor is 10 or more times higher than an initial value, that the smoothing electrolytic capacitor has deteriorated and thus detects that a failure has occurred in the smoothing electrolytic capacitor.

15. The method according to claim 11, wherein detecting the failure of the smoothing electrolytic capacitor includes switching a second switch provided at an upper portion in the inverter while a first switch provided at a lower portion in the inverter is on in order to estimate a capacitance (C) value of the smoothing electrolytic capacitor.

16. The method according to claim 15, wherein estimating the capacitance (C) value of the smoothing electrolytic capacitor includes estimating a capacitance (C) value of the smoothing electrolytic capacitor using the following equation from a change that has been made in the DC voltage of the inverter during the switching of the second switch:
$$\hat{C} = \frac{{DT}_{s} \cdot {I}_{as , dc}}{Δ {v}_{c}} ,$$
where D is a duty, Tₛ is a switching frequency, Δv_{c} is a discharged level of the inverter DC voltage, and I_{as,dc} is an average of the motor phase current.

17. The method according to claim 16, wherein detecting the failure of the smoothing electrolytic capacitor includes determining, when the estimated C value of the smoothing electrolytic capacitor is 0.6 or less times an initial value, that the smoothing electrolytic capacitor has deteriorated and thus detects that a failure has occurred in the smoothing electrolytic capacitor.

18. The method according to claim 10, further comprising displaying detection of failure of the smoothing electrolytic capacitor.

19. The apparatus according to claim 1, wherein the controller estimates the ESR value of the smoothing electrolytic capacitor without measuring a voltage of a surface of the smoothing electrolytic capacitor.

20. The method according to claim 10, wherein estimating an ESR value of the smoothing electrolytic capacitor does not include measuring a voltage of a surface of the smoothing electrolytic capacitor.
